(19) United States
(12) Patent Application Publication
(10) Pub. No.: US 2026/0164837 A1
(43) Pub. Date: Jun. 11, 2026

(54) GALLIUM NITRIDE CONTAINING HIGH SPEED PHOTODIODE DEVICE AND RELATED METHOD

(71) Applicant: KYOCERA CORPORATION, Kyoto (JP)

(72) Inventors: Changmin Lee, Goleta, CA (US); Islam Sayed, Fremont, CA (US)

(73) Assignee: KYOCERA CORPORATION, Kyoto (JP)

(21) Appl. No.: 18/972,697

(22) Filed: Dec. 6, 2024

(51) Int. Cl. H10F 71/00; H10F 30/222; H10F 77/124; H10F 77/14; H10F 77/30; H10F 77/40

(52) U.S. Cl. CPC H10F 71/139; H10F 30/222; H10F 71/1274; H10F 77/12485; H10F 77/146; H10F 77/147; H10F 77/306; H10F 77/413

(57) ABSTRACT

Techniques, including a method and device, for fabricating a high-speed photodiode device is provided. The device, in some configurations, includes a gallium and nitrogen containing epitaxial region, including a p-type and n-type regions configured on a thin substrate member. In an example, the device has both n-type and p-type contact regions configured in a planar arrangement.

### BACKGROUND

Photodiodes are semiconductor devices designed to convert incident light into electrical current through the photoelectric effect. When photons strike the active region of the photodiode, electron-hole pairs are generated, producing a current that is proportional to the intensity of the incoming light. The diode devices are typically constructed from materials such as silicon or gallium arsenide, chosen for their sensitivity to specific ranges of light wavelengths. The operational characteristics of photodiodes include responsivity, which measures their efficiency in converting light power into electrical current; spectral response, which defines the range of wavelengths they can detect; and response time, which dictates the speed at which the device can react to changes in light intensity.

Photodiodes are commonly employed in high-speed applications involving visible light, such as optical communication systems, visible light communication (VLC) technologies, laser-based sensing and ranging (LiDAR), and high-speed imaging systems. In these contexts, their ability to detect rapid changes in light intensity is desirable to performance. However, photodiodes are subject to certain limitations that may impact their effectiveness in high-speed applications. For instance, their response time can be constrained by factors such as the capacitance of the photodiode and the transit time required for carriers to traverse the depletion region. Noise, including shot noise and thermal noise, further affects the accuracy of the photodiode's output, particularly in low-light conditions. Additionally, photodiodes can become saturated at high light intensities, compromising their functionality in scenarios requiring a wide dynamic range.

Other limitations include sensitivity to temperature variations, which can alter the device's responsivity and noise characteristics, and a dependence on the wavelength of incident light, as materials like silicon exhibit reduced efficiency at the extreme ends of the visible spectrum.

From the above, it is seen that improved photodiodes are still desirable.

### SUMMARY OF INVENTION

The present disclosure relates to techniques, including methods and devices, for optical technology. In particular, and without limitation, the present disclosure provides methods, devices, and structures for optical devices, and in particular, photo diodes, commonly called photo sensors.

In an example, the present disclosure provides a photodiode device. The device has a substrate member comprising a surface region and a backside region and configured with a thickness of 200 microns and less and a mirror coating on the backside region of the substrate member. The device has a nucleation material overlying the surface region, a plurality of defect migration layers overlying the second gallium and nitrogen containing material such that the plurality of defect migration layers comprising alternating gallium nitride and indium gallium nitride regions, a lower barrier material overlying the plurality of defect migration layers, and a plurality of absorber layers overlying the lower barrier material such that the plurality of absorber layers comprising alternating indium gallium nitride regions. In an example, device has a first upper barrier material overlying the plurality of absorber layers, a second upper barrier material overlying the first upper barrier material, a contact material overlying the second upper barrier material, and a mesa structure configured from at least the contact material, the second upper barrier material, the first upper barrier material the plurality of absorber layers, and the lower barrier material. The substate member has a transparent anode overlying the contact material. In an example, the device has a cathode coupled to the substrate member.

In an example, the present disclosure provides a method of forming a photodiode device. The method includes providing a substrate member comprising a surface region and a backside region, forming a nucleation material overlying the surface region, and forming a plurality of defect migration layers overlying the second gallium and nitrogen containing material such that the plurality of defect migration layers comprising alternating gallium nitride and indium gallium nitride regions. In an example, the method includes forming a lower barrier material overlying the plurality of defect migration layers, forming a plurality of absorber layers overlying the lower barrier material such that the plurality of absorber layers comprising alternating indium gallium nitride regions, and forming a first upper barrier material overlying the plurality of absorber layers. The method includes forming a second upper barrier material overlying the first upper barrier material, forming a contact material overlying the second upper barrier material, forming a mesa structure configured from at least the contact material, the second upper barrier material, the first upper barrier material the plurality of absorber layers, and the lower barrier material. The method includes forming a transparent anode overlying the contact material and forming a cathode coupled to the substrate member. The method includes thinning the substrate member from the backside region to a thickness of 200 microns and less and forming a mirror coating on a resulting backside region of the substrate member.

In an example, the present disclosure provides a photodiode device. The device has a donor substrate. The donor substrate has a gallium and nitrogen containing material and a plurality of defect migration layers coupled to the gallium and nitrogen containing material, such that the plurality of defect migration layers comprising alternating gallium nitride and indium gallium nitride regions. The donor substrate has a lower barrier material coupled to the plurality of defect migration layers, a plurality of absorber layers coupled the lower barrier material such that the plurality of a plurality of absorber layers comprising alternating indium gallium nitride regions, a first upper barrier material coupled to the plurality of absorber layers, and a second upper barrier material coupled to the first upper barrier material. The donor substate has a contact material coupled to the second upper barrier material and a mesa structure configured from at least the contact material, the second upper barrier material, the first upper barrier material, the plurality of absorber layers, the lower barrier material, the plurality of defect migration layers, and the second gallium and nitrogen containing material. In an example, the donor substate has a blanket dielectric layer covering the mesa structure and configured to form a sidewall on an edge of at least the mesa structure, a via structure configured in the blanket dielectric layer to expose a portion of the contact material, and an upper contact material overlying and electrically connected to the contact material through the via structure and configured to form an p-type pad region and an n-type pad region.

In an example, the device has a carrier substrate coupled to the donor substrate. The carrier substrate comprises a first pattern for a p-type contact and a second pattern for an n-type contact such that the p-type contact is electrically connected to the p-type pad region and the n-type contact is electrically connected to the n-type pad region.

In an example, the present disclosure provides a donor substrate for a photodiode device. The donor substrate includes a substrate member comprising a surface region, a nucleation material overlying the surface region, a first gallium and nitrogen containing material overlying the nucleation material, a sacrificial region overlying the first gallium and nitrogen containing material, and an etching stop material overlying the sacrificial region. In an example, the donor substrate has a second gallium and nitrogen containing material overlying the etch stop material.

In an example, the donor substrate has a plurality of defect migration layers overlying the second gallium and nitrogen containing material. In an example, the plurality of defect migration layers comprises alternating gallium nitride and indium gallium nitride regions. The substrate has a lower barrier material overlying the plurality of defect migration layers, a plurality of absorber layers overlying the lower barrier material, which comprise alternating indium gallium nitride regions, a first upper barrier material overlying the plurality of absorber layers, and a second upper barrier material overlying the first upper barrier material.

In an example, the donor substrate has a contact material overlying the second upper barrier material, a first mesa structure configured from at least the contact material, the second upper barrier material, the first upper barrier material, the plurality of absorber layers, the lower barrier material, the plurality of defect migration layers, and the second gallium and nitrogen containing material. In an example, the substate has a second mesa structure configured from at least the sacrificial region. In an example, the substrate has a blanket dielectric layer overlying the first mesa structure and configured to form a sidewall on an edge of at least the first mesa structure, a via structure configured in the blanket dielectric layer to expose a portion of the contact material, and an upper contact material overlying and electrically connected to the contact material through the via structure.

In an example, the present disclosure provides a method of fabricating a high-speed photodiode device. The method includes providing a donor substate member comprising a surface region, a nucleation material overlying the surface region of the donor substrate member, a first gallium and nitrogen containing material overlying the nucleation material, a sacrificial region overlying the first gallium and nitrogen containing material, and an etching stop material overlying the sacrificial region. In an example, the donor substrate member has a second gallium and nitrogen containing material overlying the etch stop material and a plurality of defect migration layers overlying the second gallium and nitrogen containing material such that the plurality of defect migration layers comprising alternating gallium nitride and indium gallium nitride regions. In an example, the donor substrate has a lower barrier material overlying the plurality of defect migration layers, a plurality of absorber layers overlying the lower barrier material such that the plurality of absorber layers comprising alternating indium gallium nitride regions, a first upper barrier material overlying the plurality of absorber layers, a second upper barrier material overlying the first upper barrier material, a p-type contact material overlying the second upper barrier material, and a first mesa structure configured from at least the p-type contact material, the second upper barrier material, the first upper barrier material, the plurality of absorber layers, the lower barrier material, the plurality of defect migration layers, and the second gallium and nitrogen containing material. In an example, the donor substrate has a blanket dielectric layer overlying the first mesa structure and configured to form a sidewall on an edge of at least the first mesa structure, a via structure configured in the blanket dielectric layer to expose a portion of the p-type contact material, an upper p-type contact material overlying and electrically connected to the p-type contact material through the via structure, and an upper n-type contact material overlying the second gallium and nitrogen containing material and configured such that the upper n-type contact material and the upper p-type contact material are characterized by a planar region to align a n-type surface of the n-type contact material with a p-type surface of the upper p-type contact material.

In an example, the method includes flipping the donor substrate member. In an example, the method includes bonding the upper n-type contact material and the upper p-type contact material to an n-type pad region and a p-type pad region, respectively, of a carrier substrate member and then removing the donor substrate member by detaching the sacrificial region from the etch stop material.

In an alternative example, the method includes bonding a donor substrate comprising a photodiode device to a carrier member and releasing a transfer substrate from the donor substrate.

Depending upon the example, some embodiments can achieve one or more of these benefits and/or advantages. In an example, the present disclosure provides a novel photo diode device having improved features. In an example, the device is compact and spatially efficient. In an example, some embodiments offer advantages of sensitive detection capabilities configured from an efficient size, weight, and cost using the present techniques. By utilizing these photodiodes for optical energy conversion, various benefits can be achieved, including the avoidance of electromagnetic interference, immunity from electromagnetic noise, power beaming in free space, and providing a unique data transmission link when combined with optical communication. These and other benefits and/or advantages are achievable with the present device and related methods. Further details of these benefits and/or advantages can be found throughout the present specification and more particularly below.

A further understanding of the nature and advantages of the invention may be realized by reference to the latter portions of the specification and attached drawings.

### BRIEF DESCRIPTION OF THE DRAWINGS

In order to more fully understand the present invention, reference is made to the accompanying drawings. Understanding that these drawings are not to be considered limitations in the scope of the invention, the presently described embodiments and the presently understood best mode of the invention are described with additional detail through use of the accompanying drawings in which:

FIG. 1 is a simplified cross-sectional view diagram of an example of a high-speed photodiode device according to some embodiments.

FIG. 2 is a more detailed diagram of the example high-speed photodiode device according to some embodiments.

FIG. 3 is a more detailed view of an example of an epitaxial region for a high-speed photodiode device according to some embodiments.

FIGS. 4 and 4A are simplified diagrams illustrating examples of an impact of well thickness and an impact of barrier thickness.

FIGS. 5 and 5A are simplified diagrams illustrating examples of an InGaN quantum barrier having a higher responsivity, bandwidth, and saturation voltage at a lower bias in a photodiode device according to some embodiments.

FIG. 6 is a simplified diagram illustrating an example of reflectance against wavelength for a photodiode device according to some embodiments.

FIG. 7 is a simplified diagram of an example of a photodiode device using a sidewall chemical treatment according to some embodiments.

FIG. 8 is a simplified illustration of an example of sidewall leakage suppression for a photodiode device according to some embodiments.

FIG. 9 is a simplified illustration of an example of a high-speed photodiode device according to some embodiments.

FIG. 10 is a simplified illustration of an example of a backside reflector for a high-speed photodiode device configured with a thinned, polished, mirror applied substrate according to some embodiments.

FIG. 11 is a simplified cross-sectional diagram of an example of a high-speed photodiode device according to an alternative example of some embodiments.

FIG. 12 is a simplified diagram of an example of a flip chip method for manufacturing a high-speed photodiode according to some embodiments.

FIG. 13 is a simplified flow diagram of an example of a method for manufacturing a high-speed photodiode according to some embodiments.

FIG. 14 is a simplified diagram of an example of a flip chip donor configured as a high-speed photodiode (for improved backside reflection) according to some embodiments.

FIG. 15 are illustrations of simplified drawings of examples of various examples of integrated high-speed photodiodes according to some embodiments.

FIG. 16 illustrates an example of various optical configurations for a high-speed photodiode according to some embodiments.

FIG. 17 is a simplified diagram of an example of a high-speed photo diode configured on a CMOS wafer according to some embodiments.

FIG. 18 is a simplified diagram of an example of an array of high-speed photo diodes according to some embodiments.

FIG. 19 is a simplified diagram of an example of a multi-wavelength device transfer according to some embodiments.

FIG. 20 is a simplified diagram of an example of a multi-wavelength device transfer according to some embodiments.

FIG. 21 is a simplified diagram of an example of a muti-wavelength device transfer according to some embodiments.

FIG. 22 is a simplified diagram of an example of a multi-device transfer according to some embodiments.

FIG. 23 is a simplified diagram of an example of a donor substrate transfer method according to some embodiments.

FIG. 24 is a simplified diagram of an example of various high-speed photodiode devices according to some embodiments.

FIG. 25 is a simplified illustration of an example of a band diagram with an epitaxial structure for a device according to some embodiments.

FIG. 26 is a simplified illustration of an example of a performance metric table according to to some embodiments.

FIG. 27 is a simplified illustration of an example of photocurrent and quantum efficiency and bandwidth according to some embodiments.

FIG. 28 is a simplified diagram of an example of a visible light communication system according to some embodiments.

FIG. 29 is a simplified system diagram of an example of a Light Detection and Ranging (LiDAR) system according to some embodiments.

### DETAILED DESCRIPTION OF THE EXAMPLES

The ensuing description provides preferred exemplary embodiment(s) only, and is not intended to limit the scope, applicability, or configuration of the disclosure. Rather, the ensuing description of the preferred exemplary embodiment(s) will provide those skilled in the art with an enabling description for implementing a preferred exemplary embodiment. It is understood that various changes may be made in the function and arrangement of elements without departing from the spirit and scope as set forth in the appended claims.

According to the present disclosure, techniques related to methods and devices for optical technology are provided. In particular, the present disclosure provides methods, devices, and structures for optical devices, and in particular, photo diodes, commonly called photo sensors. In an example, the disclosure provides a method for fabricating an optical device, e.g., photodiode. What follows is a general description of some example configurations and example fabrications of these devices.

Photodiodes are commonly employed in high-speed applications involving visible light, such as optical communication systems, visible light communication (VLC) technologies, laser-based sensing and ranging (LiDAR), and high-speed imaging systems. In these contexts, their ability to detect rapid changes in light intensity is desirable to performance. However, photodiodes are subject to certain limitations that may impact their effectiveness in high-speed applications. For instance, their response time can be constrained by factors such as the capacitance of the photodiode and the transit time required for carriers to traverse the depletion region. Noise, including shot noise and thermal noise, further affects the accuracy of the photodiode's output, particularly in low-light conditions. Additionally, photodiodes can become saturated at high light intensities, compromising their functionality in scenarios requiring a wide dynamic range. Other limitations include sensitivity to temperature variations, which can alter the device's responsivity and noise characteristics, and a dependence on the wavelength of incident light, as materials like silicon exhibit reduced efficiency at the extreme ends of the visible spectrum.

Despite these challenges, various design modifications can mitigate these issues. For example, the use of avalanche photodiodes provides internal signal amplification, enhancing sensitivity. Reducing capacitance, optimizing the size of the active region, and incorporating transimpedance amplifiers can further improve the performance of photodiodes in high-speed visible light applications. These advancements enable photodiodes to meet the demands of increasingly complex systems requiring rapid and precise light detection.

In an example, the present disclosure provides various embodiments including a single monolithically integrated high-speed photodiode (HSPD) with a thinned substrate and a bonded high-speed photodiode configured from a donor substrate and a carrier member. Further details are provided throughout the present specification and more particularly below.

In an example, the present high-speed photodiode (HSPD) with InGaN quantum barrier (QB) operates at lower reverse bias with respect to GaN QB while maintaining same or better performance. In an example, a device reverse bias can be lowered, e.g., from −6 to −8V to −2 to −4V. In an example, performance metric is a modulation bandwidth, a quantum efficiency (QE %) and a plus dark current, each of which is further described throughout the present specification and more particularly below.

In an example, operation at lower reverse bias is desirable for reducing power consumption and enhancing reliability. In an example. lower reverse bias operation maintains the device with less stress resulting in better reliability. Also, with low bias condition, the operation power consumption is expected to be lower than high bias condition.

In an example, the present disclosure provides a photodiode device. The device has a substrate member comprising a surface region and a backside region and configured with a thickness, e.g., of 200 microns and less, and a mirror coating on the backside region of the substrate member. The device has a nucleation material overlying the surface region, a plurality of defect migration layers overlying the second gallium and nitrogen containing material such that the plurality of defect migration layers comprising alternating gallium nitride and indium gallium nitride regions, a lower barrier material overlying the plurality of defect migration layers, and a plurality of absorber layers overlying the lower barrier material such that the plurality of absorber layers comprising alternating indium gallium nitride regions. In an example, device has a first upper barrier material overlying the plurality of absorber layers, a second upper barrier material overlying the first upper barrier material, a contact material overlying the second upper barrier material, and a mesa structure configured from at least the contact material, the second upper barrier material, the first upper barrier material the plurality of absorber layers, and the lower barrier material. The substate member has a transparent anode overlying the contact material. In an example, the device has a cathode coupled to the substrate member.

In an example, the substrate member comprises a sapphire material, a silicon material, or a gallium and nitrogen containing material. In an example, the substrate member has a thickness suitable of preventing deflection of an overlying material. In an example, the device has a reverse bias voltage, e.g., of −2 to −6 volt. In an example, the device is characterized by a power consumption. In an example, the mirror coating comprises a dielectric material. In an example, the nucleation material comprises a gallium nitride buffer layer. In an example, the defect migration layers comprise a plurality of periodic structures with the period, e.g., ranging from 20 to 60, characterized by a plurality of alternating layers of indium gallium nitride and gallium nitride, such that the indium gallium nitride composition and thickness ranges are, e.g., 0 to 5% and 1 to 4 nm, respectively, and the gallium nitride thickness range is, e.g., 1 to 4 nm. In an example, the first upper barrier material comprises a gallium nitride material such that the first upper barrier material is in an undoped state and has thickness, e.g., ranging from 6 to 12 nm. In an example, the second upper barrier material comprises a gallium nitrogen containing material overlying the first upper barrier material and the gallium nitrogen containing material comprises a magnesium dopant material having a concentration, e.g., 8E19 atoms/cm³ to 6E10 atoms/cm³, and a thickness of sixteen nanometers to twenty-four nanometers. In an example, the lower barrier material comprises a gallium nitride material that is doped with a silicon impurity with concentration, e.g., ranging from 6E18 atoms/cm³ to 4E19 atoms/cm³ and a thickness, e.g., ranging from 5 to 12 nm.

In an example, the present disclosure provides a method of forming a photodiode device. The method includes providing a substrate member comprising a surface region and a backside region, forming a nucleation material overlying the surface region, and forming a plurality of defect migration layers overlying the second gallium and nitrogen containing material such that the plurality of defect migration layers comprising alternating gallium nitride and indium gallium nitride regions. In an example, the method includes forming a lower barrier material overlying the plurality of defect migration layers, forming a plurality of absorber layers overlying the lower barrier material such that the plurality of absorber layers comprising alternating indium gallium nitride regions, and forming a first upper barrier material overlying the plurality of absorber layers. The method includes forming a second upper barrier material overlying the first upper barrier material, forming a contact material overlying the second upper barrier material, forming a mesa structure configured from at least the contact material, the second upper barrier material, the first upper barrier material the plurality of absorber layers, and the lower barrier material. The method includes forming a transparent anode overlying the contact material and forming a cathode coupled to the substrate member. The method includes thinning the substrate member from the backside region to, e.g., a thickness of 200 microns and less, and forming a mirror coating on a resulting backside region of the substrate member.

In an example, using InGaN barrier reduce the field in quantum well thus resulting in a sharper absorption tail and improves quantum efficiency at lower bias voltages. In an example, at, e.g., 0V, GaN QB absorbs 0.12 uA while InGaN QB absorbs 1.8 uA at a certain given incident power setup. (Note: Such example is not illustrating an absolute value depending on the incident light output power). In an example, a more absolute comparison could be quantum efficiency. In an example, e.g., at 0V, GaN QB is about 17% QE but InGaN QB is 25% quantum efficiency (QE) from its higher absorption.

In an example, using InGaN barrier (less effective mass and lower barrier height) reduces carrier sweep out lifetime and enhances speed at low bias voltage. In an example, under a given bias voltage (e.g., −2V), InGaN barrier performs up to 2.4 GHz but GaN barrier performs only around 0.5 MHz—see the performance table, as will be further described below.

In an example, reducing both InGaN well and GaN barrier thickness enhances electron-hole function overlap in c-plane and reduces carrier sweep out lifetime for tunneling and thermionic emission and are desirable for achieving high-speed high responsivity.

In an example, the HSPD with sidewall pretreatment followed by dielectric passivation suppress sidewall leakage and dark current performance. In an example, the pretreatment process is to remove the etch damage of the mesa sidewall surface from the dry etch process for defining the mesa. Pretreatment process for GaN includes acid and base chemicals to remove unwanted oxide and damaged GaN surface. Such chemical includes, e.g., HCl (hydrogen chloride)->BOE (buffered oxide etch)->KOH or HCl->BOE or HCl->KOH or BOE->KOH or single chemical process. In an example, dilution should be improved or even optimized. With minimum amount of air exposure, low damage SiO₂ (silicon dioxide) or SiNₓ (silicon nitride) or Al₂O₃ (aluminum oxide) should be deposited to the sidewall by such as ALD (atmospheric low-pressure deposition) or low damage PECVD (plasma enhanced chemical vapor deposition) or ECR (electron cyclotron resonance) in an example. In an example, from our result, dark current without HCl/BOE pretreatment shows 1 nA at −2 V, however, with HCl/BOE pretreatment shows 0.01 nA at −2 V, which has significantly less dark current. See the table below and Figures. That is, we achieved a desirable result with HCl/BOE and observed that KOH pretreatment also worked favorably in an experiment according to some embodiments.

In an example, the HSPD with dual function dielectric layer made >99% anti-reflector coating on transparent contact layer. In an example, light aperture on the top of the mesa is deposited by transparent contact such as Indium Tin Oxide (ITO) (or ZnO or thin Ni/Au) for a p-type contact region. On top of ITO, the SiO² layer is deposited with specific thickness to make ITO/SiO² anti-reflective coating (ARC) and the SiO₂ expanded (larger) to cover the sidewall of the mesa. The SiO₂ layer serves as not only the top layer of ARC but passivation layer to cover the mesa sidewall. The SiO₂ can be formed using ALD (an atmospheric low pressure deposition) or ECR (electron cyclotron resonance) deposition that can provide low damage deposition as well as precision control of the thickness. A reflectivity plotted against wavelength data are in the Figure below (>99% transmission to active region, <0.01 in reflectance.

In an example, HSPD with wafer thinning and reflector film on the bottom side improves the absorption of >70%. In an example, a wafer is thinned down to <200 um by removing substrate materials and polished by chemical mechanical polisher (CMP) to make mirror-like surface followed by reflective metal deposition such as silver (Ag) or Distributed Bragg Reflector (DBR) stack to make a highly reflective (HR) coating on the polished backside surface. QE is improved from 20% to 34% at −2V. In an alternative example, the wafer is thinned down to <200 um by removing substrate materials and polished by chemical mechanical polisher (CMP) to make mirror-like surface followed by reflective metal deposition such as silver (Ag) or Distributed Bragg Reflector (DBR) stack to make HR coating on the polished backside surface. QE is improved from, e.g., 20% to 34% at −2V. 34% QE/20% QE=1.7 (e.g., 70% improvement).

These and other features and/or advantageous are described throughout the present specification and more particularly below.

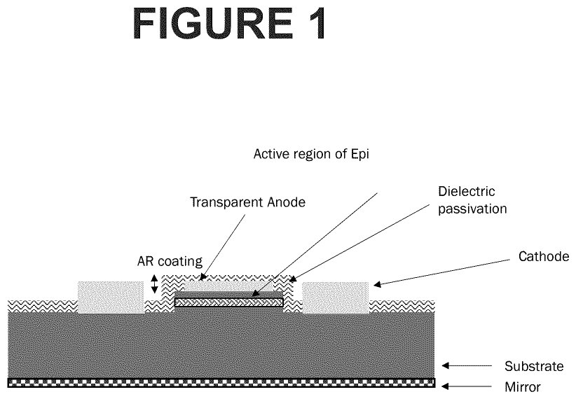

FIG. 1 is a simplified cross-sectional view diagram of a high-speed photodiode device according to some embodiments. As shown, the device is characterized as a structure for top-side illuminated photodiode device. In an example, the device has a thinned substrate member to improve and/or even maximize a trapping of light. The device has a mirror on a backside to facilitate absorption into an active region. In an example, the device is configured to reduce a path of a plurality of photons using a thinned backside, anti-reflective coating (e.g., silicon dioxide, and indium tin oxide), among other features.

Other features include a dielectric passivation, cathode contact region, and active epitaxial region, defining a p-n junction.

As shown, the substrate has an upper surface region including a cathode and an anode, which has a transparent overlying coating. The coating is an anti-reflective material, among others.

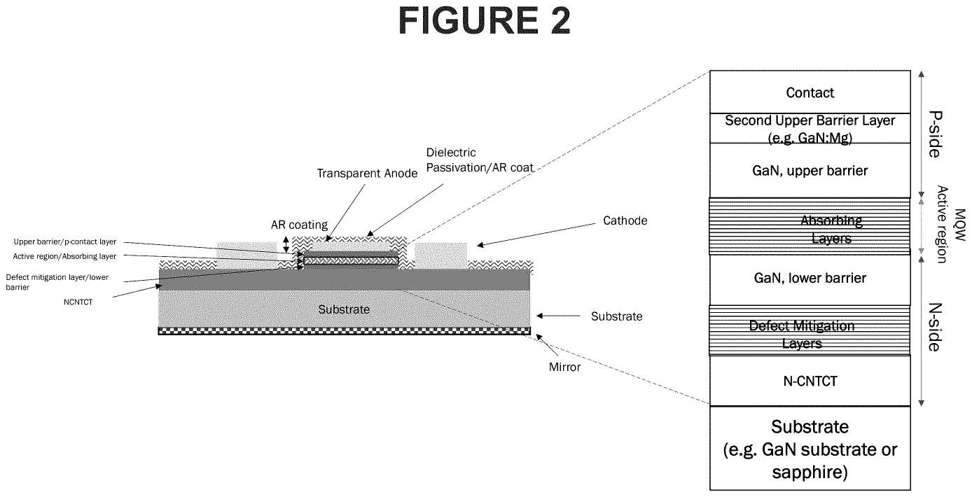

FIG. 2 is a more detailed diagram of the high-speed photodiode device according to some embodiments. An exploded view of the epitaxial region is also shown. The exploded view includes the substate, an n-type contract region, a plurality of defect mitigation layers, and a gallium nitride lower barrier material, which define an n-side region. Overlying the n-side region is a plurality of absorber layers defining a multi-quantum region layer. The device also has a gallium nitride upper barrier, a second upper barrier (e.g., GaN:Mg), and an overlying contact region. The contact region is configured as a transparent anode region, and overlying passivation material including an anti-reflective coating.

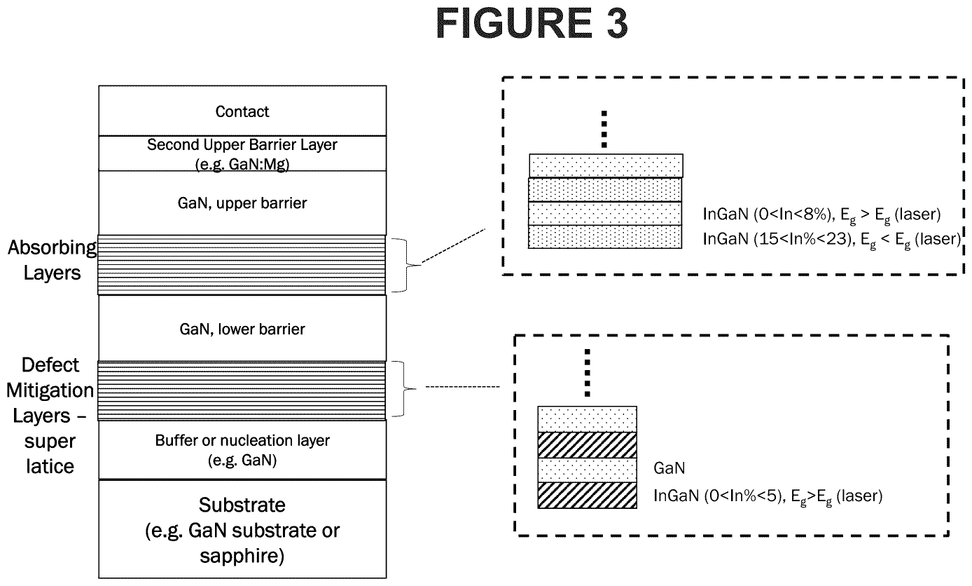

FIG. 3 is a more detailed view of an epitaxial region for a high-speed photodiode device according to some embodiments. As shown, the absorbing layers comprise an InGaN layer, which is desirable for a quantum barrier. Higher indium concentration (previously the quantum barrier was GaN) including approximately three (3) to twenty (20) periods for the layers associated with ten (10) to twelve (12) quantum wells. In an example, each of the barrier regions is ˜2.5 nm and is configured for biasing and other factors. In an example, the indium concentration has an abrupt transition between the layers. in an example, a graded layer is also desirable.

As shown, indium can range from zero to eight percent in composition of InGaN, and then fifteen to twenty three percent in composition.

In an example, a plurality of defect mitigation layers forming a super lattice comprise GaN and InGaN in an alternating structure, as shown.

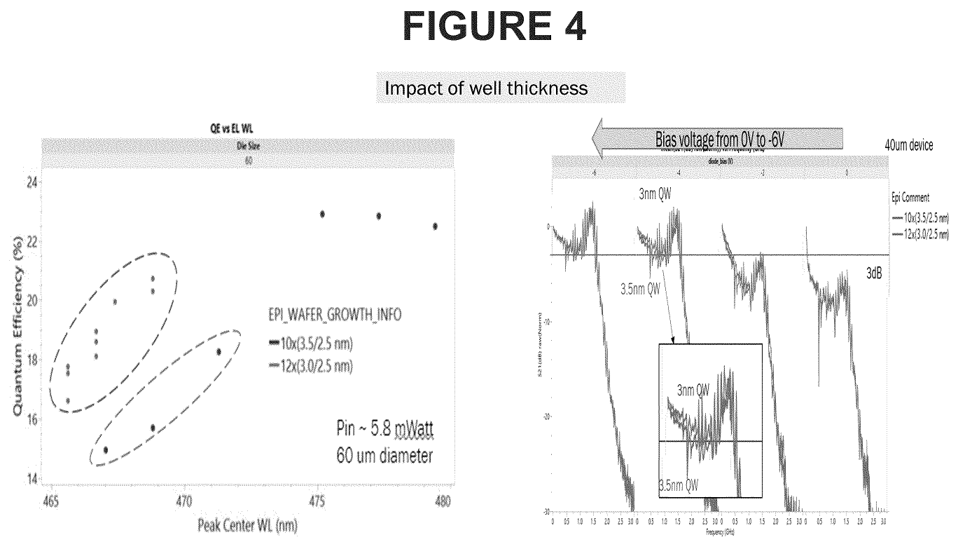

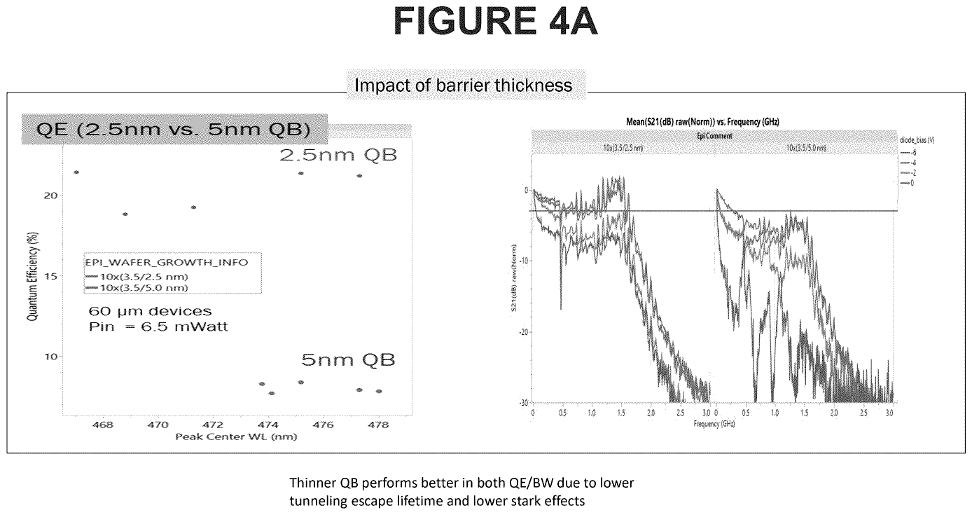

FIGS. 4 and 4A are simplified diagrams illustrating an impact of well thickness and an impact of barrier thickness according to some embodiments. As shown, the Figures show impact of well thickness and impact of barrier thickness. As shown, a thinner quantum well (QW) showed a higher quantum efficiency (QE) than a thicker QW design in same active region WL, (i) due to better E-H wave function overlap and higher absorption (ii) efficient carrier sweep out due to lower τ_th (lower barrier height) in an example.

In an example, a thinner QW design at −4V and −2V showed slightly better performance in <1 GHz range—possibly due lower effective QB height, as shown.

As also shown, a thinner QB performs better in both QE/BW due to lower tunneling escape lifetime and lower stark effects, as shown on the impact of barrier thickness.

Overall, c-plane gallium nitride has a strong polarization and quantum confined Stark effect (QCSE) which becomes more severe with a higher Indium, a thicker wells, and thicker barriers. As a result, thin well/barriers are desirable for efficient carrier sweep out, high MQW absorption, and high device bandwidth (BW).

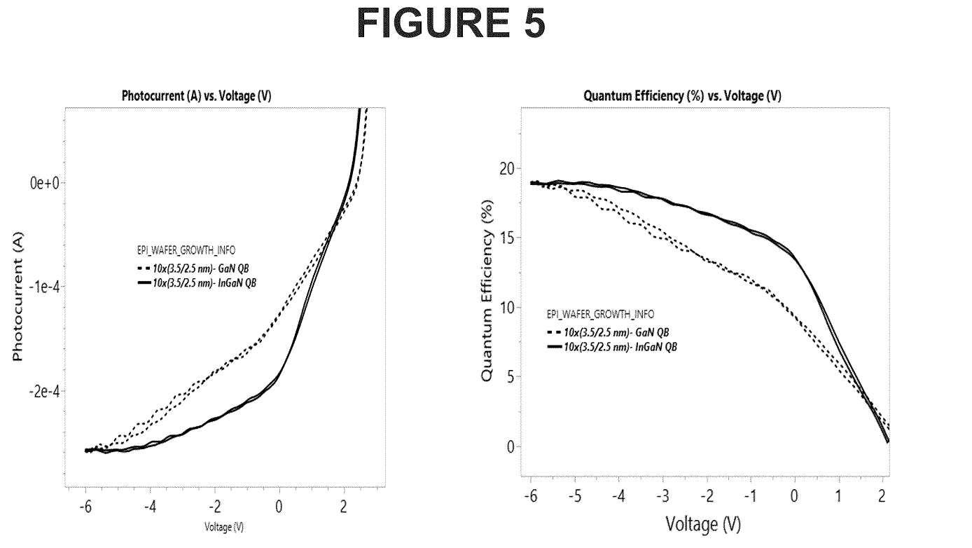

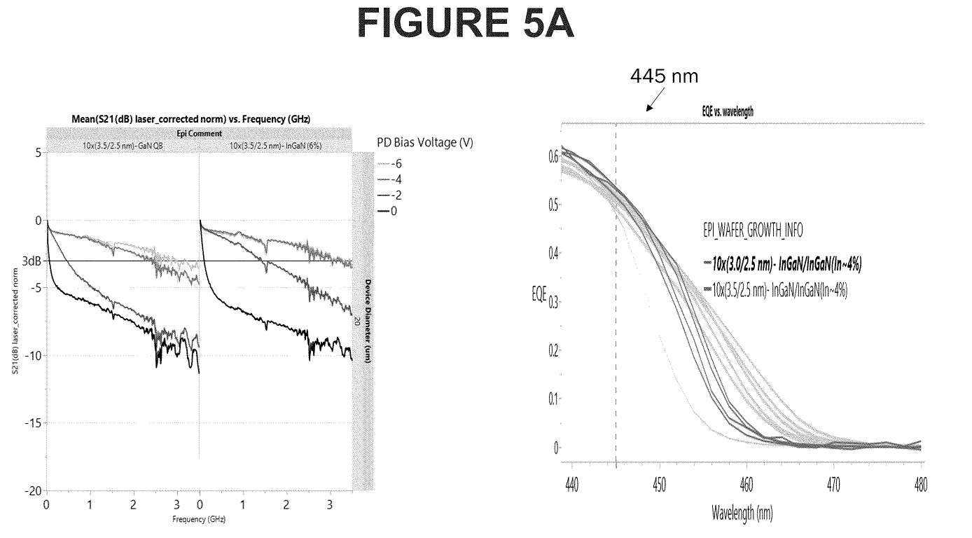

FIGS. 5 and 5A are simplified diagrams illustrating an InGaN quantum barrier having a higher responsivity, bandwidth, and saturation voltage at a lower bias in a photodiode device according to some embodiments. As shown, the device with the InGaN QB operates at a lower reverse bias voltage with respect to a GaN quantum barrier while maintaining a same or improved performance. In an example, using the InGaN barrier reduces a field in the well region resulting in a sharper absorption tail and improves a responsivity and quantum efficiency at a lower reverse bias voltage. In an example, such barrier with less efficient mass and lower barrier height reduces carrier sweep out lifetime and enhances speed.

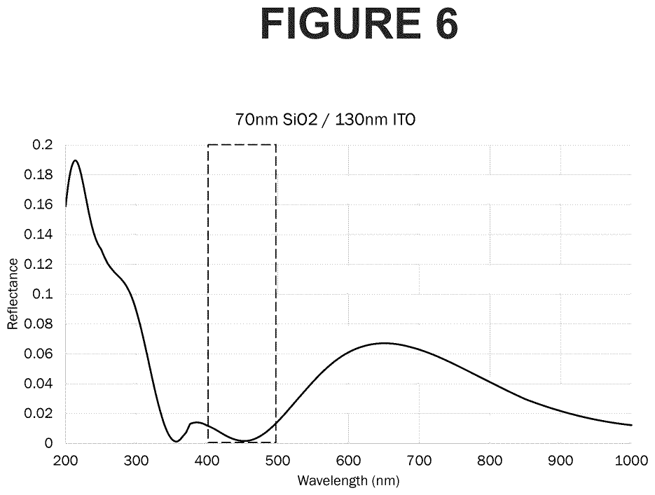

FIG. 6 is a simplified diagram illustrating reflectance against wavelength for a photodiode device according to some embodiments. The diagram is a plot of reflectance plotted against wavelength in nanometers, nm. Configured with silicon dioxide, ITO, and antireflective coating, the present device includes a transparent contact to absorb light. In an example, the device has a passivation layer as part of ARC to absorb more, reflect less, and perform other features to target 450 nm wavelength for the optimization.

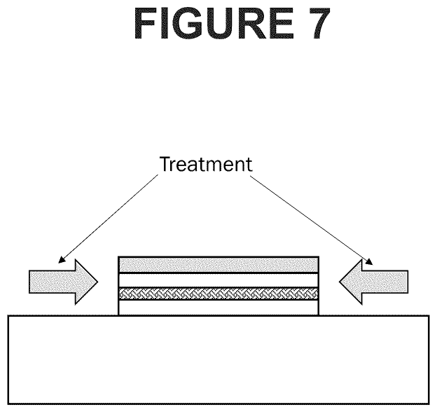

FIG. 7 is a simplified diagram of a photodiode device using a sidewall chemical treatment according to some embodiments. In an example, chemical treatment for leakage current suppression is desirable for high-speed photo diodes. In an example, to minimize leakage current through sidewall, the present technique performs a special treatment on sidewall. The treatment includes a combination of hydrochloric acid and buffered oxide etch applied to sidewalls or other features of the mesa structure, as shown.

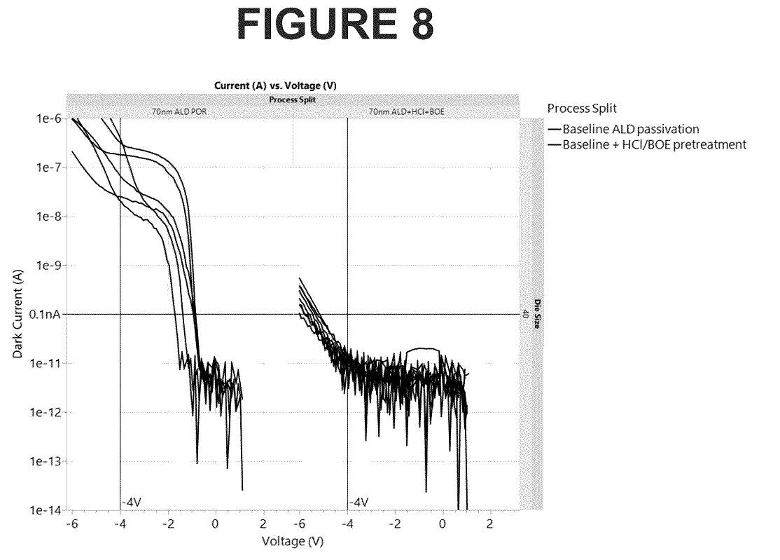

FIG. 8 is a simplified illustration of sidewall leakage suppression for a photodiode device according to some embodiments. The plot shows dark current in amperes plotted against voltage. The right side is a control device, while the left side is a device using the present pre-treatment technique to some embodiments. As shown are experimental results using chemical treatment of hydrogen chloride and buffered oxide etchant. As shown, dark current has been suppressed or even eliminated at about −2 volts. See control on left side, against pretreatment on right side of plot. As shown, leakage has been suppressed using the chemical treatment on the high-speed photo diodes.

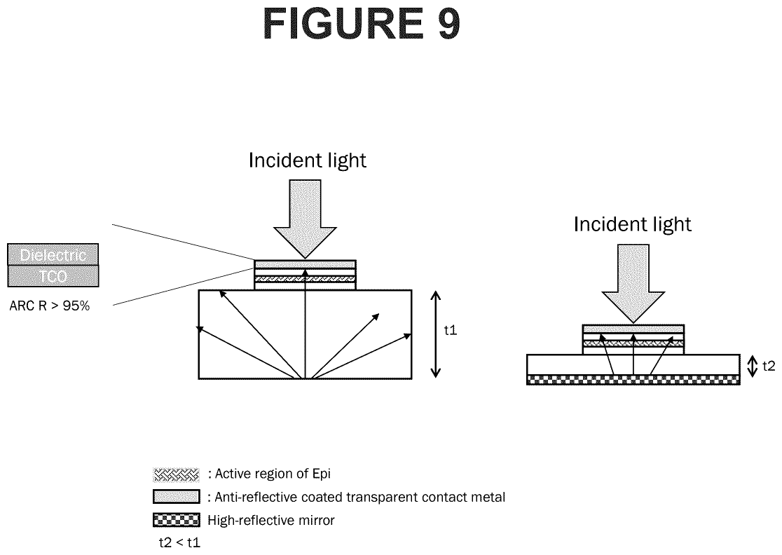

FIG. 9 is a simplified illustration of a high-speed photodiode device according to some embodiments. In an example, the drawing on the left is a conventional photodiode device for comparison, while the drawing on the right is for a high-speed photodiode device according to some embodiments. In an example, the present device has a backside mirror that is different. In an example, the device is free from a roughened surface from a small compact size. In an example, the device has been configured to reflect light exactly back to device area such that a surface of the backside has been polished to minimize roughness of backside and then the mirror surface has been applied. In an example, the mirror surface is smooth and free from surface roughness.

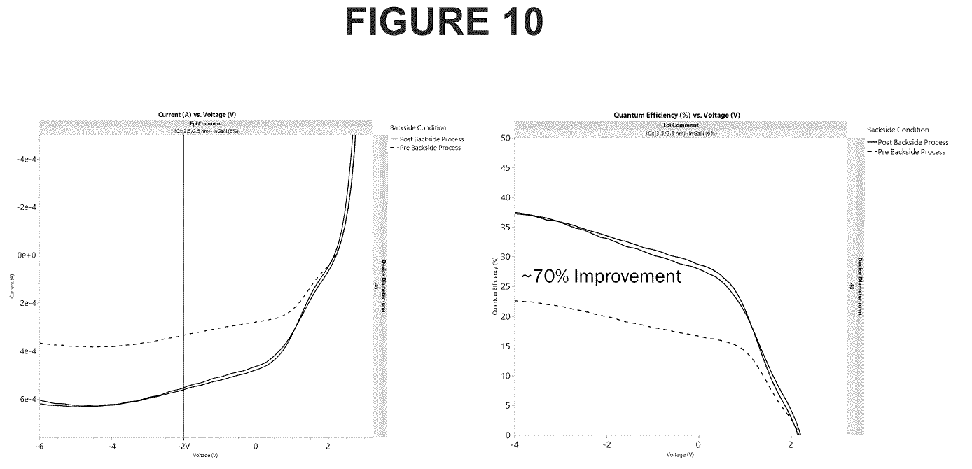

FIG. 10 is a simplified illustration of a backside reflector for a high-speed photodiode device configured with a thinned, polished, mirror applied substrate according to some embodiments.

Further details of some embodiments of the present invention can be found throughout the present specification and more particularly below.

In an example, the present disclosure provides for manufacturing a high-speed photo diode using a die expansion process configured with layer transfer. In an example, such process has benefits and/or advantageous of saving a significant amount of donor materials (GaN) compared to topside conventional process because the nature of high-speed photodiode requires donor/mesa area to be small. In an example, the process is also efficient for manufacturing an array architecture, which can facilitate applications, including but not limited to multi-WL chip array (WDM), multi-chip array (spatial division multiplexing), focal plane array (e.g., LiDAR), phased array (e.g., LiDAR), and dispersive array (for prism LiDAR—WL (wave-length) dependent emission angle), among other applications.

In an example, the present disclosure provides a donor substrate for a photodiode device. The donor substrate includes a substrate member comprising a surface region, a nucleation material overlying the surface region, a first gallium and nitrogen containing material overlying the nucleation material, a sacrificial region overlying the first gallium and nitrogen containing material, and an etching stop material overlying the sacrificial region. In an example, the donor substrate has a second gallium and nitrogen containing material overlying the etch stop material.

In an example, the donor substrate has a plurality of defect migration layers overlying the second gallium and nitrogen containing material. In an example, the plurality of defect migration layers comprises alternating gallium nitride and indium gallium nitride regions. The substrate has a lower barrier material overlying the plurality of defect migration layers, a plurality of absorber layers overlying the lower barrier material, which comprise alternating indium gallium nitride regions, a first upper barrier material overlying the plurality of absorber layers, and a second upper barrier material overlying the first upper barrier material.

In an example, the donor substrate has a contact material overlying the second upper barrier material, a first mesa structure configured from at least the contact material, the second upper barrier material, the first upper barrier material, the plurality of absorber layers, the lower barrier material, the plurality of defect migration layers, and the second gallium and nitrogen containing material. In an example, the substate has a second mesa structure configured from at least the sacrificial region. The first mesa structure and the second mesa structure may, for example, be a mesa structure that is wider at the top or a mesa structure that is wider at the bottom. In an example, the substrate has a blanket dielectric layer overlying the first mesa structure and configured to form a sidewall on an edge of at least the first mesa structure, a via structure configured in the blanket dielectric layer to expose a portion of the contact material, and an upper contact material overlying and electrically connected to the contact material through the via structure.

In an example, the substrate member is selected from a sapphire substrate or a gallium and nitrogen containing substrate. The nucleation material comprises a gallium nitride material comprising a silicon material. In an example, the first gallium and nitrogen containing material is unintentionally doped and the second gallium and nitrogen containing material is unintentionally doped. In an example, the sacrificial region comprises InGaN characterized by an indium composition ranging from 12 to 18%, and a thickness from 2 to 4 nm. In an example, the etch stop material comprises AlGaN characterized by an Al composition ranging from 10 to 20%, and a thickness from 10 to 30 nm. In an example, the second gallium and nitrogen containing material comprises GaN having a thickness ranging from 5 to 45 nm. In an example, the defect migration layers comprising the alternating gallium nitride and indium gallium nitride regions and the defect migration layers are characterized by one or more periodic structures with a period ranging from 20 to 60 such that the periodic structures having a plurality of alternating layers of indium gallium nitride and gallium nitride such that the indium gallium nitride is characterized by a composition of 0 to 5% and a thickness of 1 to 4 nm and the gallium nitride having a thickness range of 1 to 4 nm.

In an example, the lower barrier material comprise GaN doped with a silicon with a concentration ranging from 6E18 atoms/cm3 to 4E19 atoms/cm3 and a thickness ranging from 5 to 12 nm. In an example, the plurality of absorber layers range from five to thirty; and the plurality of defect migration layers range from twenty to sixty. In an example, the first upper barrier material comprises GaN characterized by an undoped state and has thickness ranging from 6 to 12 nm. In an example, the second upper barrier material comprises GaN such that the upper barrier (UB 2) gallium nitrogen containing material is overlying the first upper barrier material, the second upper barrier gallium nitrogen containing material comprises a magnesium dopant material having a concentration 8E19 atoms/cm³ to 6E10 atoms/cm³, and a thickness of sixteen nanometers to twenty-four nanometers. In an example, the contact material comprises GaN having a thickness is 10-20 nm with a magnesium doping concentration ranging from 1e20 to 4e20 atoms/cm³.

In an example, the donor substrate also has a silicon carbide substrate comprising an overlying metal material bonded to the upper contact material and configured to allow the substrate material to lift off and be removed using the sacrificial region. In an example, the donor substrate also has one or more anchor regions mechanically coupling the upper contact material to the substrate member. In an example, the blanket dielectric layer is selected from at least one of a SiO₂ (silicon dioxide), silicon nitride, silicon oxynitride, aluminum oxide (Al2O3), or ZnO (zinc oxide), among others. In an example, the substate has one or more anchor regions mechanically coupling the upper contact material to the substrate material and the one or more anchor regions are configured from the upper contact material.

In an example, the present disclosure provides an alternative photodiode device. The device has a donor substrate. The donor substrate has a gallium and nitrogen containing material and a plurality of defect migration layers coupled to the gallium and nitrogen containing material, such that the plurality of defect migration layers comprising alternating gallium nitride and indium gallium nitride regions. The donor substrate has a lower barrier material coupled to the plurality of defect migration layers, a plurality of absorber layers coupled the lower barrier material such that the plurality of a plurality of absorber layers comprising alternating indium gallium nitride regions, a first upper barrier material coupled to the plurality of absorber layers, and a second upper barrier material coupled to the first upper barrier material. The donor substate has a contact material coupled to the second upper barrier material and a mesa structure configured from at least the contact material, the second upper barrier material, the first upper barrier material, the plurality of absorber layers, the lower barrier material, the plurality of defect migration layers, and the second gallium and nitrogen containing material. In an example, the donor substate has a blanket dielectric layer covering the mesa structure and configured to form a sidewall on an edge of at least the mesa structure, a via structure configured in the blanket dielectric layer to expose a portion of the contact material, and an upper contact material overlying and electrically connected to the contact material through the via structure and configured to form an p-type pad region and an n-type pad region.

In an example, the device has a carrier substrate coupled to the donor substrate. The carrier substrate comprises a first pattern for a p-type contact and a second pattern for an n-type contact such that the p-type contact is electrically connected to the p-type pad region and the n-type contact is electrically connected to the n-type pad region.

In an example, the carrier substrate is selected from a sapphire substrate, a silicon substrate, a glass substrate, a silicon on insulator substrate, or a gallium and nitrogen containing substrate.

In an example, the present disclosure provides a method of fabricating a high-speed photodiode device. The method includes providing a donor substate member comprising a surface region, a nucleation material overlying the surface region of the donor substrate member, a first gallium and nitrogen containing material overlying the nucleation material, a sacrificial region overlying the first gallium and nitrogen containing material, and an etching stop material overlying the sacrificial region. In an example, the donor substrate member has a second gallium and nitrogen containing material overlying the etch stop material and a plurality of defect migration layers overlying the second gallium and nitrogen containing material such that the plurality of defect migration layers comprising alternating gallium nitride and indium gallium nitride regions. In an example, the donor substrate has a lower barrier material overlying the plurality of defect migration layers, a plurality of absorber layers overlying the lower barrier material such that the plurality of absorber layers comprising alternating indium gallium nitride regions, a first upper barrier material overlying the plurality of absorber layers, a second upper barrier material overlying the first upper barrier material, a p-type contact material overlying the second upper barrier material, and a first mesa structure configured from at least the p-type contact material, the second upper barrier material, the first upper barrier material, the plurality of absorber layers, the lower barrier material, the plurality of defect migration layers, and the second gallium and nitrogen containing material. In an example, the donor substrate has a blanket dielectric layer overlying the first mesa structure and configured to form a sidewall on an edge of at least the first mesa structure, a via structure configured in the blanket dielectric layer to expose a portion of the p-type contact material, an upper p-type contact material overlying and electrically connected to the p-type contact material through the via structure, and an upper n-type contact material overlying the second gallium and nitrogen containing material and configured such that the upper n-type contact material and the upper p-type contact material are characterized by a planar region to align a n-type surface of the n-type contact material with a p-type surface of the upper p-type contact material.

In an example, the method includes flipping the donor substrate member to position such donor substrate to be bonded, as will be described below.

In an example, the method includes bonding the upper n-type contact material and the upper p-type contact material to an n-type pad region and a p-type pad region, respectively, of a carrier substrate member and then removing the donor substrate member by detaching the sacrificial region from the etch stop material.

In an example, the method is also configured for backside processing and design freedom. Such method provides for flexibility of flipped backside for an anti-reflective coating (ARC), a Distributed Bragg reflector (DBR), color filter, BPF, grating, microlens, among others.

In an example, the method and related device can include an optical cavity. In an example, the cavity is configured for reflective p-type side down device with thin p-GaN offers shorter optical path from the reflection. In an example, the method allows for selection of various carrier wafers. In an example, the HSPD can be transferred to different types of carrier wafers (e.g., SiC, silicon dioxide, glass, silicon, silicon on insulator) to consider different characteristics such as heat, RF (radio frequency), cost, among others. In an example, the method also facilitates for contact pads on non-conductive substrate can improve parasitic capacitance resulting in high-speed performance.

These and other features and/or advantageous are described throughout the present specification and more particularly below.

As will be shown below, the present high-speed photodiode device is formed using a first substrate member, which is flipped and bonded onto a second substrate member according to some embodiments. The first substrate member has been described in more detail in reference to the Figure below.

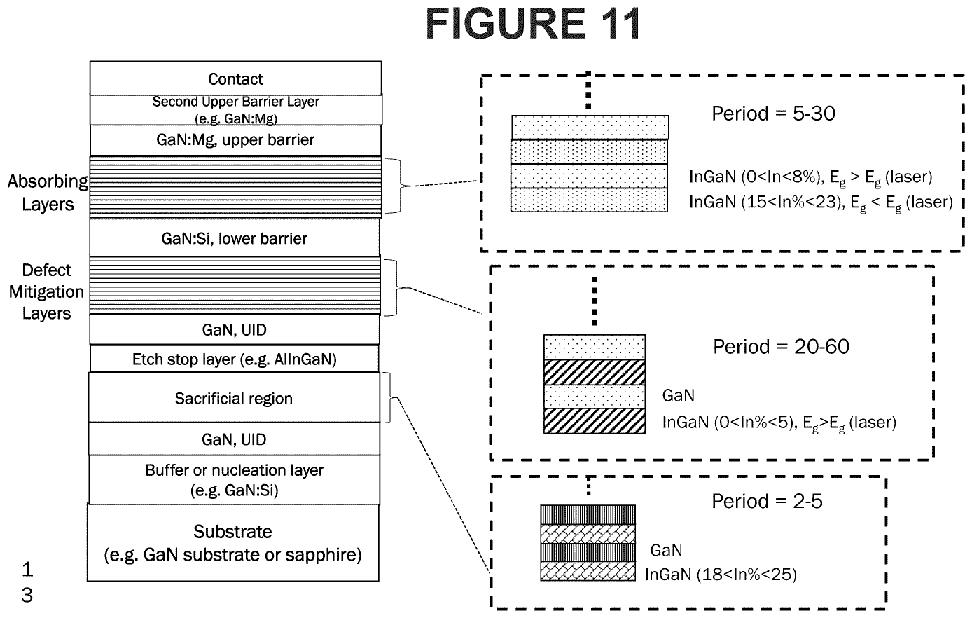

FIG. 11 is a simplified cross-sectional diagram of a high-speed photodiode device according to some embodiments. As shown, the device is configured using a sacrificial region to break off and transfer an epitaxial structure including gallium nitride. The device has a substate, e.g., GaN, sapphire, or others. The device has an overlying buffer or nucleation layer overlying a surface of the substrate. The layer is made of a gallium nitride crystal doped with silicon. In an example, the device has an overlying unintentionally doped region (UID), e.g., GaN. The device has a sacrificial region. The sacrificial region comprises alternating InGaN and GaN regions, as shown. In an example, the alternating regions have a period of 2.5 or greater. In an example, the device has an overlying etch stop layer, e.g., AlInGaN, a GaN layer, and an overlying plurality of defection mitigation layers.

In an example, the defect mitigation layers include alternating InGaN and GaN regions, as shown. In an example, the alternating regions comprise a period ranging from twenty to sixty or more.

In an example, the device has a lower barrier region. The lower barrier region is made of a gallium nitride with silicon material. In an example, the device has a plurality of absorbing layers. The absorbing layers have alternating InGaN regions including a first concentration of indium and a second concentration of indium. The indium ranges from zero to eight in the first concentration range, and fifteen to twenty-three in the second concentration range. The alternating regions have a period ranging from five to thirty or more in an example.

In an example, the device has an overlying upper barrier, e.g., GaN—Mg, a second upper barrier layer, e.g., GaN—Mg, and a contact region, as shown.

In an example, the aforementioned structure is configured to be flipped onto a substrate member to form a high-speed photodiode.

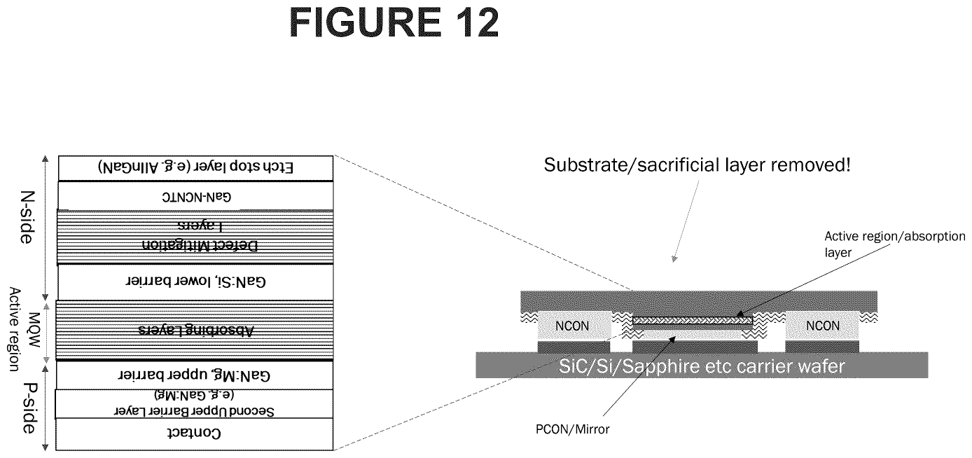

FIG. 12 is a simplified diagram of a flip chip method for manufacturing a high-speed photodiode according to some embodiments. As shown, the structure of the prior Figure is flipped and bonded to p-type contact and mirror region formed on a carrier substrate. As shown, the structure is configured to remove the substrate via the sacrificial layer.

In an example, the carrier wafer, e.g., silicon carbide, sapphire, others, includes contact regions, as shown.

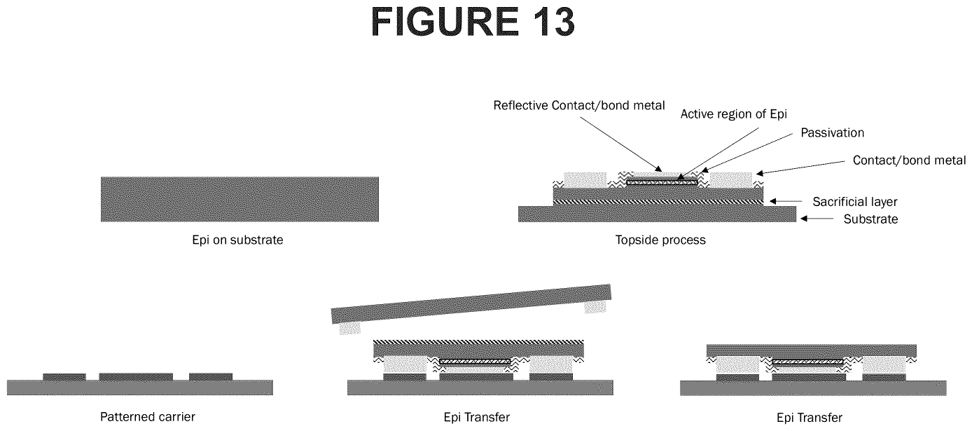

FIG. 13 is a simplified flow diagram of a method for manufacturing a high-speed photodiode according to some embodiments. In an example, the present method forms a donor substrate, including epitaxial regions. Generally, the method forms the donor, which is flipped, and then transferred to a carrier substrate. In an example, the donor includes contact regions, e.g., bond pads, for both p-type and n-type contacts. As shown, both p-type and n-type are formed on one side of the substrate member. As also shown is a patterned carrier substrate. The donor substrate is flipped bonded on to the patterned carrier substrate, and the epitaxial region is transferred removing the substrate from the donor substrate. As shown, the carrier is pre-patterned for the transmission lines in an example,

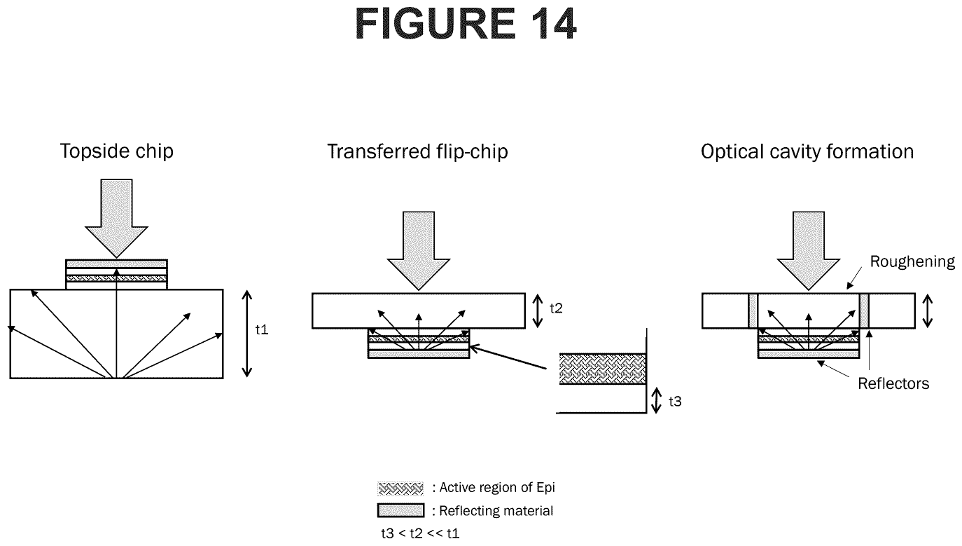

FIG. 14 is a simplified diagram of a flip chip donor configured as a high-speed photodiode according to some embodiments. As shown, a topside chip has a substrate with a thickness, t1. The transferred flip chip has a substate thickness of t2, which is less than t1. The flip-chip has reflectors, epitaxial region, and substate member, which is roughened.

In an example, the flip chip is thin without an additional thinning step. In an example, a highly reflective mirror for the p-contact (e.g., p is at the bottom in this example). The carrier wafer has reflectors pre-built to configure an optical cavity, e.g., ˜2 um, to allow for transparency.

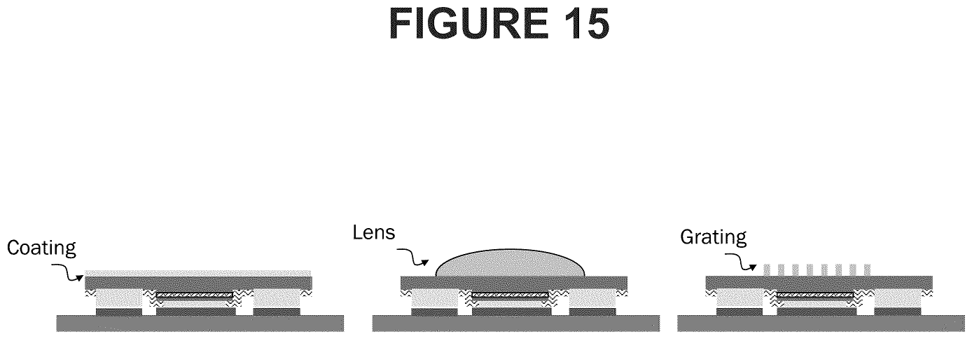

FIG. 15 are illustrations of simplified drawings of various examples of integrated high-speed photodiodes according to some embodiments. As shown, the devices include a top side coating, lens, or grating. Other elements can also be included. In an example, the coating can be an antireflective coating, color filter coating, nanoparticle coating, among others. In an example, the lens includes a microlens, a focal plane, adaptive optics, among others. In an example, the grating includes diffractive, refractive, prism, among others. Of course, there can be other variations.

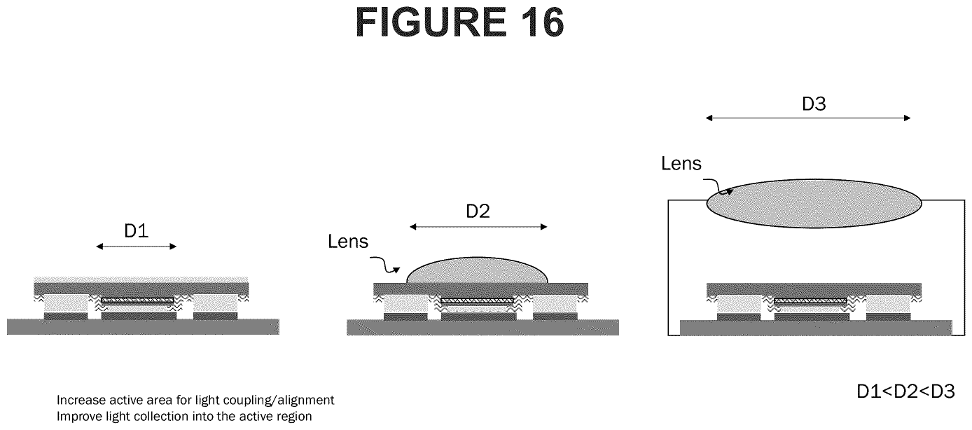

FIG. 16 illustrates various optical configurations for a high-speed photodiode according to some embodiments. As shown, an area is increased for light coupling from D1, D2, to D3. D1 includes an overlying optical material. D2 includes a lens structure configured on an optical cavity region. D3 includes a lens configured above an optical cavity region. The lens is separated by a free space gap region.

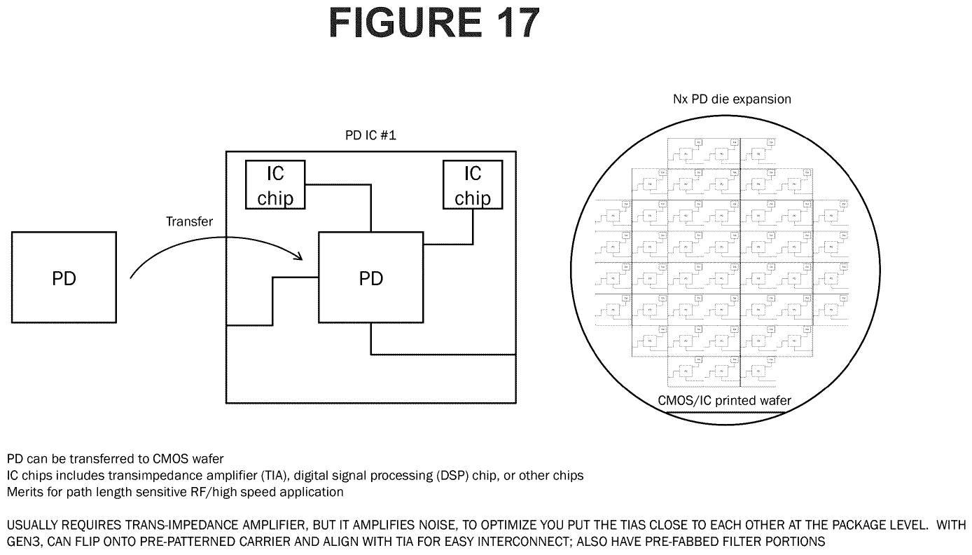

FIG. 17 is a simplified diagram of a high-speed photo diode configured on a CMOS wafer according to an example of the present system. In an example, the photodiode is formed on a CMOS wafer, including various integrated circuit chips, e.g., transimpedance amplifier, digital signal processor, application specific integrated circuits, and others.

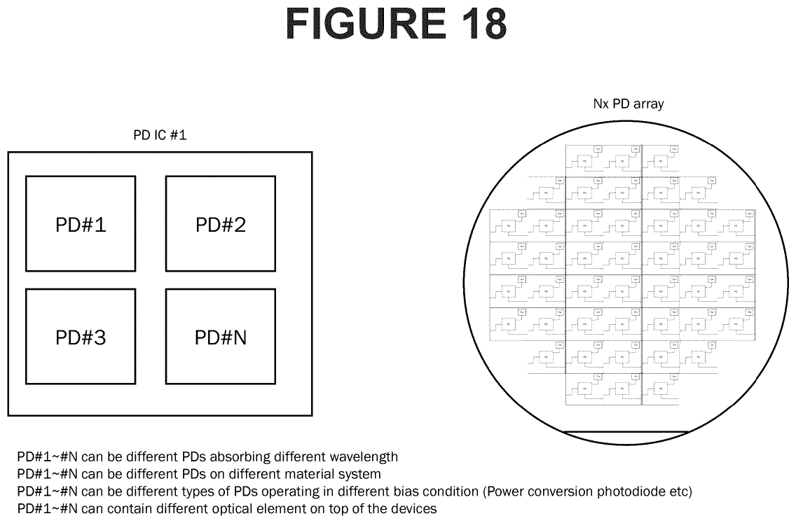

FIG. 18 is a simplified diagram of an array of high-speed photo diodes according to an example of the present system. As shown, the diagram includes an array of high-speed gallium nitride (GaN) photodiodes designed for enhanced optical signal detection across a wide range of ultraviolet (UV) and visible light wavelengths. The photodiodes within the array are engineered with varying absorption characteristics, operational speeds, and structural configurations, enabling superior performance in high-intensity, high-frequency, and environmentally demanding applications. The use of GaN as the primary semiconductor material offers advantages due to its wide bandgap, high thermal stability, and inherent resistance to radiation, making it ideal for use in harsh environments and high-energy photon detection.

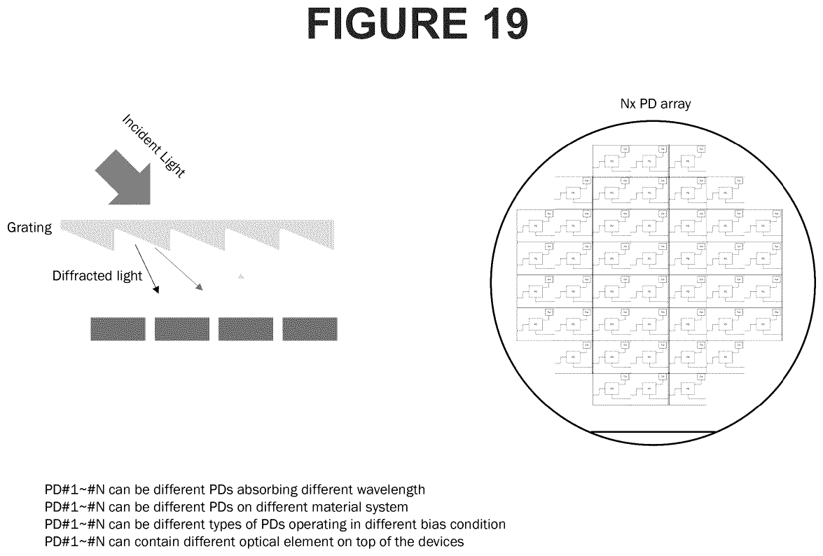

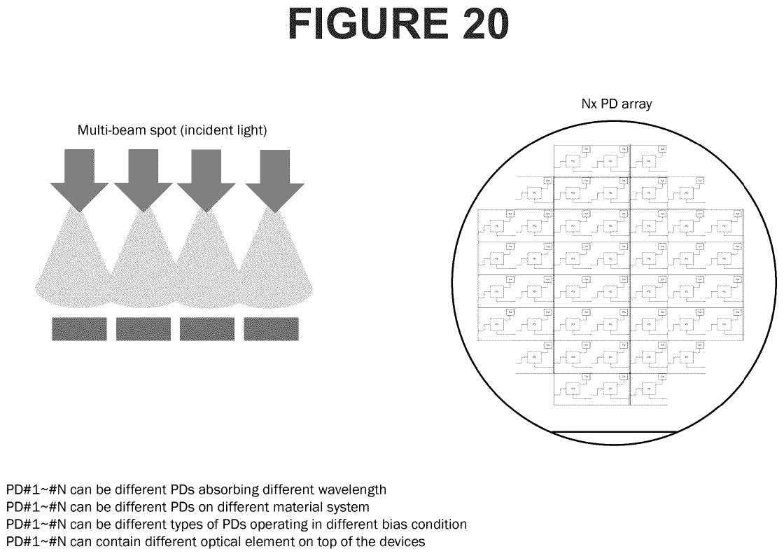

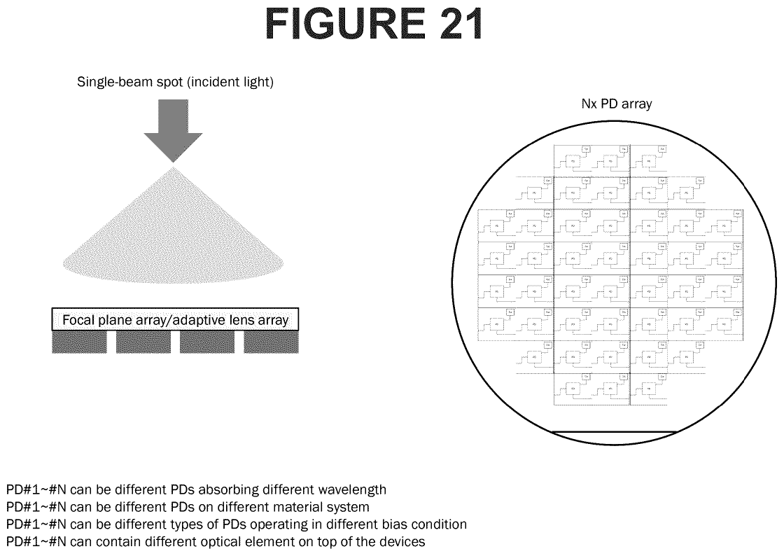

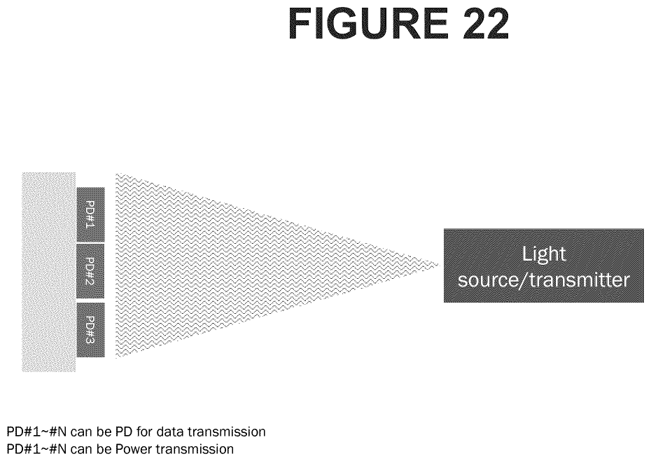

Other examples are provided throughout the present specification and more particularly below. FIG. 19 is a simplified diagram of a multi-wavelength device transfer according to some embodiments. FIG. 20 is a simplified diagram of a multi-wavelength device transfer according to some embodiments. FIG. 21 is a simplified diagram of a muti-wavelength device transfer according to some embodiments. FIG. 22 is a simplified diagram of a multi-device transfer according to some embodiments.

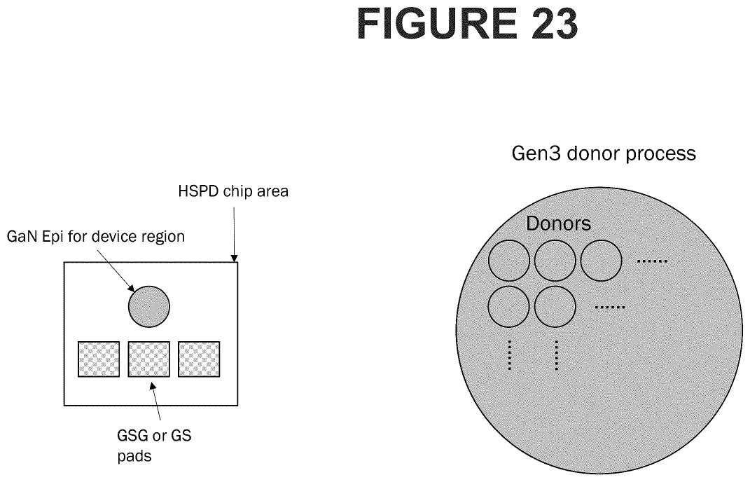

FIG. 23 is a simplified diagram of a donor substrate transfer method according to some embodiments. As shown, a small portion of the donor is included, saving material costs for a chip area of the high-speed photodiode.

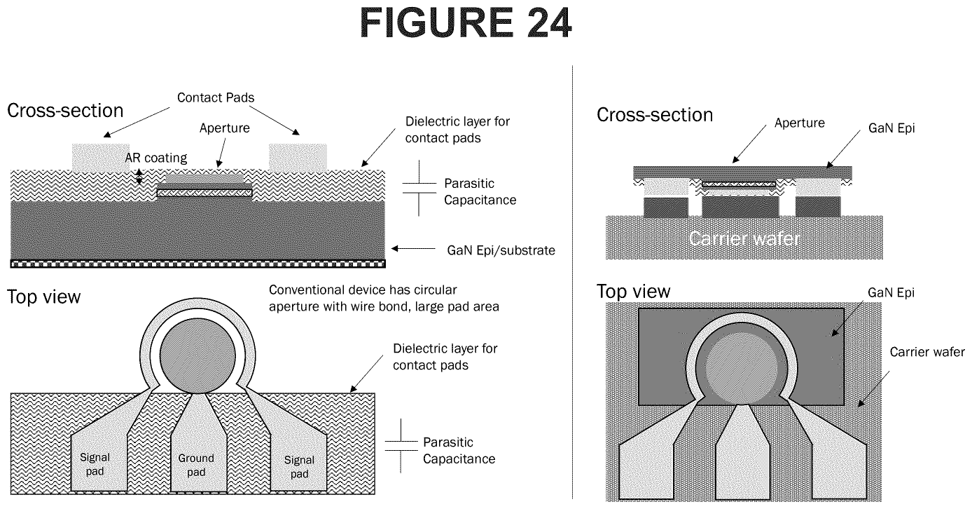

FIG. 24 is a simplified diagram of various high-speed photodiode devices according to some embodiments. As shown the device on the right hand side has been flipped onto carrier thereby having little or no parasitic capacitance. That is, electrodes are directly connected from top side of pad to bottom. The electrodes or wirings are on the same plane, as shown. As shown on the left hand side is a device in an earlier example of an embodiment. Both views include side and top view illustrations.

In an example, the design on the right side discloses a parasitic capacitance-free design for high-speed gallium nitride (GaN) photodiodes, offering improvements in performance and manufacturing efficiency. In other examples, large contact pads, such as ground-signal-ground (GSG) configurations, are positioned directly on the conductive GaN substrate. To mitigate parasitic capacitance associated with these pads, thick dielectric or polymeric layers are required beneath the pads. While this design reduces parasitic effects, such designs limits the speed and performance of the photodiodes, particularly in high-frequency applications.

In an example, the techniques include a design that eliminates the need for large pads on the conductive GaN substrate. Instead, the photodiodes are directly bonded onto a pad-patterned carrier, bypassing the requirement for intermediate dielectric layers. This innovative bonding approach results in a reduction in parasitic capacitance, thereby enhancing the photodiode's overall high-speed performance.

By removing the thick dielectric layers and directly bonding to the carrier, the second-generation design offers several advantages, such as reduced capacitance, enhanced speed and bandwidth, and improved manufacturing method, among others. In an example, the direct bonding method significantly reduces the capacitance typically generated between the RF pads and the substrate, resulting in improved high-frequency response and signal integrity. In an example, reduction in parasitic capacitance allows the photodiodes to operate at gigahertz-range bandwidths, making them ideal for applications that demand high-speed signal processing, such as optical communication, LiDAR, and advanced sensing systems. In an example, by eliminating the need for thick dielectric layers, the fabrication method is simplified, reducing both the number of production steps and associated costs.

In an example, the parasitic capacitance-free design offers a transformative solution for high-speed GaN photodiodes, delivering enhanced performance, reduced complexity, and cost-effective scalability for a wide range of high-speed optical applications.

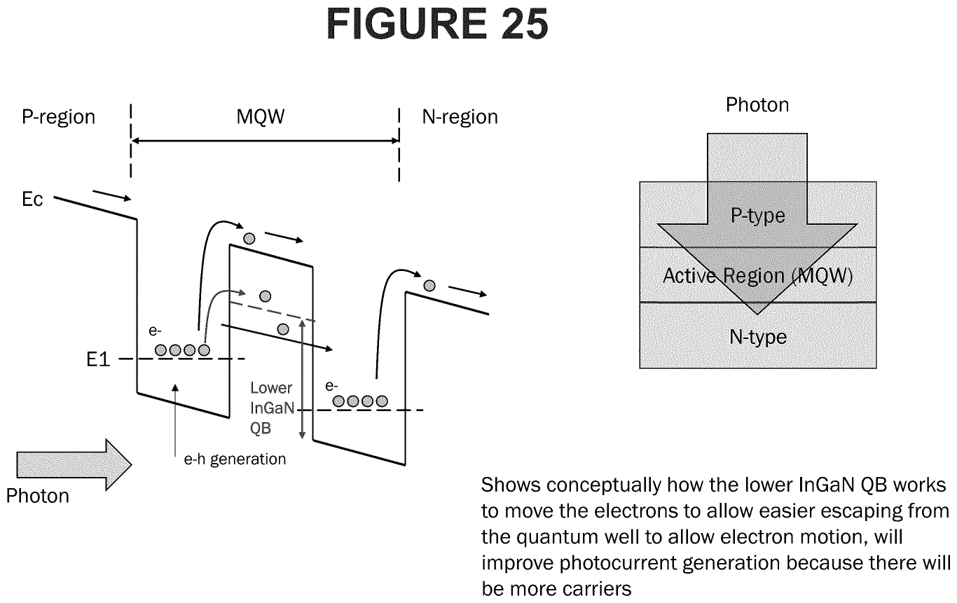

FIG. 25 is a simplified illustration of a band diagram with an epitaxial structure for a device according to some embodiments. As shown, a photon traverses through p-type, active region, and n-type regions. Electrons escape from the quantum well configured with a lower energy in a InGaN quantum barrier region, as shown.

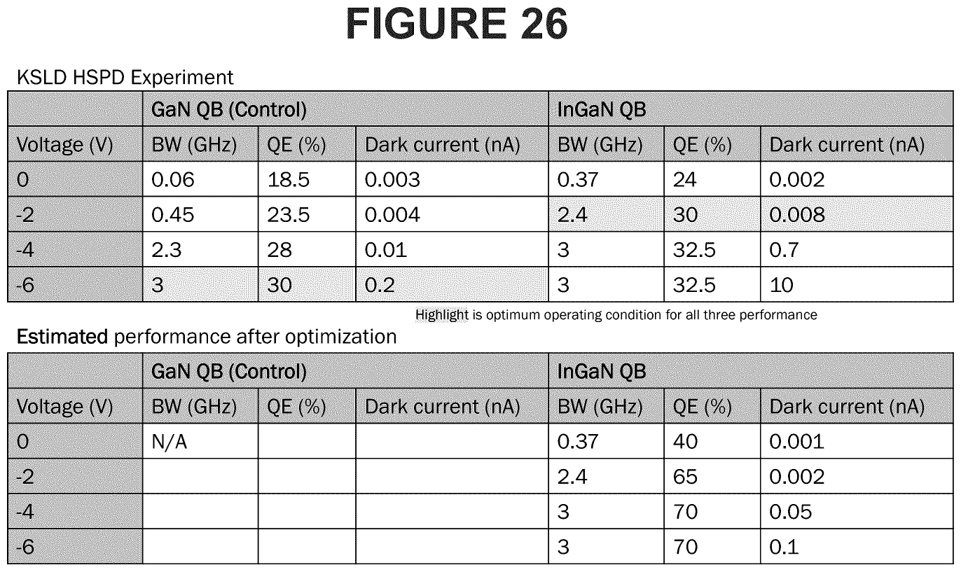

FIG. 26 is a simplified illustration of a performance metric table according to some embodiments.

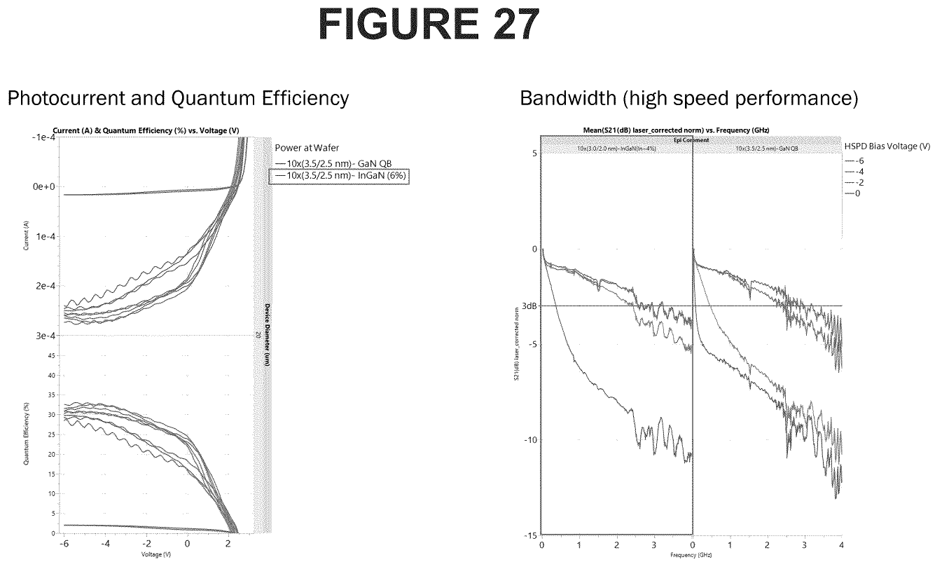

FIG. 27 is a simplified illustration of photocurrent and quantum efficiency and bandwidth according to some embodiments.

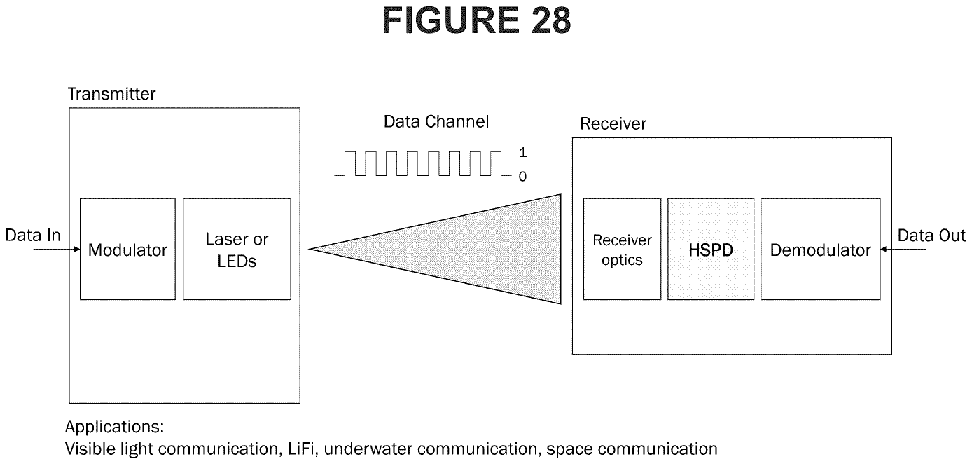

FIG. 28 is a simplified diagram of a visible light communication system according to some embodiments. As shown is a visible light communication (VLC) system designed to transmit data through a free-space communication medium using modulated visible light. The system comprises a transmitter that encodes and transmits data and a receiver that decodes the transmitted optical signals, enabling high-speed wireless communication over a line-of-sight channel.

In an example, the transmitter includes a data input interface configured to receive digital signals from an external source, such as audio, video, or internet data. The data input is coupled to a modulator, which processes the incoming digital signals and converts them into an optical transmission format. The modulation may utilize techniques such as On-Off Keying (OOK), Pulse Width Modulation (PWM), or Orthogonal Frequency Division Multiplexing (OFDM) to efficiently encode the data onto a visible light signal. This modulation ensures accurate data transfer even at high transmission speeds.

In an example, the modulated signal is directed to a high-speed laser diode capable of emitting visible light within the 400 to 700 nm wavelength range. The laser diode is designed for operation at gigahertz (GHz) frequencies, allowing rapid modulation and enabling high data rates. The laser is optically coupled to a free-space communication medium, such as air, facilitating the transmission of data without physical cabling or waveguides. This setup offers low signal attenuation and high bandwidth, making it particularly suitable for short-to medium-range communication applications.

In an example, the receiver side of the system is equipped with optics designed to collect and focus the incoming modulated light signal. These receiver optics, which may include lenses or mirrors, direct the light onto a high-speed photodetector, ensuring minimal signal loss and maximizing sensitivity. The photodetector, which can be a gallium nitride containing photodiode, converts the incoming light signal into an electrical signal. The photodetector is engineered to handle high-frequency signals with minimal distortion, supporting data rates in the gigabit-per-second range.

In an example, the electrical signal from the photodetector is processed by a demodulator, which decodes the optical signal by applying the inverse of the modulation technique used at the transmitter. The demodulator may incorporate advanced error correction algorithms to ensure data integrity, particularly in environments subject to optical noise or interference. The decoded data is then transmitted via a data output interface to its final destination, such as a network system, display device, or computing unit.

In an example, the VLC system is particularly well-suited for applications requiring high bandwidth and low latency, including indoor wireless networks, automotive communication systems such as vehicle-to-vehicle (V2V) and vehicle-to-infrastructure (V2I) communication, smart lighting systems that combine illumination and data transmission, and industrial automation environments where traditional radio frequency communication is impractical due to electromagnetic interference.

By integrating high-speed optical components with robust modulation and demodulation techniques, this VLC system provides a fast, secure, and interference-free communication solution for a wide range of data transmission applications.

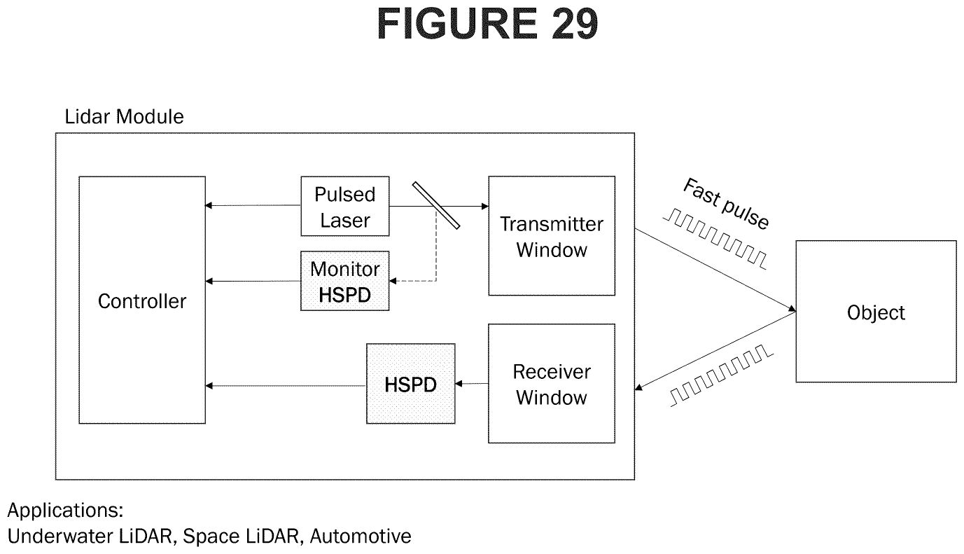

FIG. 29 is a simplified system diagram of a Light Detection and Ranging (LiDAR) system according to some embodiments. As shown, the LiDAR system designed for high-speed object detection and tracking comprises a pulsed laser source, a beam steering transmitter, a high-speed photodiode receiver, and a central controller for signal processing. The system operates by emitting laser pulses from the laser source, directing these pulses toward a target object via the transmitter, and collecting the reflected light with the receiver. The reflected light is converted into electrical signals by the high-speed photodiode, allowing precise distance and velocity measurements to be calculated.

The pulsed laser source may be a solid-state or fiber laser operating at a wavelength suitable for eye safety. The laser is capable of generating narrow pulses in the nanosecond range with adjustable pulse rates ranging from 10 kHz to several MHz, ensuring both high-resolution scanning and real-time responsiveness.

In an example, the transmitter incorporates a beam-steering mechanism that directs the laser pulses toward the target. This mechanism may utilize mechanical components such as rotating mirrors or solid-state alternatives like microelectromechanical systems (MEMS) mirrors or optical phased arrays. The transmitter is designed to cover a wide field of view (FoV) for broad area scanning or a narrow FoV for focused object tracking.

In an example, the reflected laser pulses are captured by a receiver equipped with optical components that focus the incoming light onto a high-speed photodiode. Optical filters are integrated into the receiver to minimize interference from ambient light by allowing only light at the laser's specific wavelength to pass through. The photodiode, which may be an avalanche photodiode (APD) or a PIN photodiode, exhibits a high-frequency response in the gigahertz range, enabling it to detect rapid, weak signals with high accuracy.

In an example, a central controller, typically comprising a microcontroller or field-programmable gate array (FPGA), governs the operation of the system. The controller synchronizes the emission of laser pulses, acquisition of reflected signals, and subsequent processing. A digital signal processor (DSP) is employed to filter the received signals, perform noise reduction, and compute the time-of-flight (ToF) data, which is used to determine the distance and velocity of the target object. Advanced algorithms can further enhance object recognition and tracking capabilities, enabling the system to differentiate between various objects and track their movements in real time.

In an example, the LiDAR system is particularly suited for applications requiring precise, high-speed object detection and tracking. Potential uses include autonomous vehicles for obstacle detection and avoidance, robotics for environmental mapping and navigation, industrial automation for monitoring high-speed conveyor systems, and security systems for perimeter detection and intrusion tracking.

In an example, the integration of a high-speed photodiode and advanced control algorithms ensures superior accuracy and responsiveness, making the system well-suited for environments requiring rapid and reliable object detection and tracking.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A donor substrate for a photodiode device comprising:
a substrate member comprising a surface region;
a nucleation material overlying the surface region;
a first gallium and nitrogen containing material overlying the nucleation material;
a sacrificial region overlying the first gallium and nitrogen containing material;
an etching stop material overlying the sacrificial region;
a second gallium and nitrogen containing material overlying the etch stop material;
a plurality of defect migration layers overlying the second gallium and nitrogen containing material, the plurality of defect migration layers comprising alternating gallium nitride and indium gallium nitride regions;
a lower barrier material overlying the plurality of defect migration layers;
a plurality of absorber layers overlying the lower barrier material, the plurality of absorber layers comprising alternating indium gallium nitride regions;
a first upper barrier material overlying the plurality of absorber layers;
a second upper barrier material overlying the first upper barrier material;
a contact material overlying the second upper barrier material;
a first mesa structure configured from at least the contact material, the second upper barrier material, the first upper barrier material, the plurality of absorber layers, the lower barrier material, the plurality of defect migration layers, and the second gallium and nitrogen containing material;
a second mesa structure configured from at least the sacrificial region;
a blanket dielectric layer overlying the first mesa structure and configured to form a sidewall on an edge of at least the first mesa structure;
a via structure configured in the blanket dielectric layer to expose a portion of the contact material; and
an upper contact material overlying and electrically connected to the contact material through the via structure.

2. The donor substrate for the photodiode device of claim 1 wherein the substrate member is selected from a sapphire substrate or a gallium and nitrogen containing substrate.

3. The donor substrate for the photodiode device of claim 1 wherein the nucleation material comprises a gallium nitride material or comprises a silicon material.

4. The donor substrate for a photodiode device of claim 1 wherein the contact material comprises GaN having a thickness is 10-20 nm with a magnesium doping concentration ranging from 1e20 to 4e20 atoms/cm³.

5. The donor substrate for the photodiode device of claim 1 further comprising a silicon carbide substrate comprising an overlying metal material bonded to the upper contact material and configured to allow the substrate material to lift off and be removed using the sacrificial region.

6. The donor substrate for the photodiode device of claim 1 further comprising one or more anchor regions mechanically coupling the upper contact material to the substrate member.

7. The donor substrate for the photodiode device of claim 1 wherein the blanket dielectric layer is selected from at least one of a SiO₂ (silicon dioxide), silicon nitride, silicon oxynitride, aluminum oxide (Al2O3), or ZnO (zinc oxide).

8. The donor substrate for the photodiode device of claim 1 further comprising one or more anchor regions mechanically coupling the upper contact material to the substrate material and the one or more anchor regions are configured from the upper contact material.

9. A photodiode device comprising:
a donor substrate comprising:
a gallium and nitrogen containing material;
a plurality of defect migration layers coupled to the gallium and nitrogen containing material, the plurality of defect migration layers comprising alternating gallium nitride and indium gallium nitride regions;
a lower barrier material coupled to the plurality of defect migration layers;
a plurality of absorber layers coupled the lower barrier material, the plurality of a plurality of absorber layers comprising alternating indium gallium nitride regions;
a first upper barrier material coupled to the plurality of absorber layers;
a second upper barrier material coupled to the first upper barrier material;
a contact material coupled to the second upper barrier material;
a mesa structure configured from at least the contact material, the second upper barrier material, the first upper barrier material, the plurality of absorber layers, the lower barrier material, the plurality of defect migration layers, and the gallium and nitrogen containing material;
a blanket dielectric layer covering the mesa structure and configured to form a sidewall on an edge of at least the mesa structure;
a via structure configured in the blanket dielectric layer to expose a portion of the contact material;
an upper contact material overlying and electrically connected to the contact material through the via structure and configured to form an p-type pad region and an n-type pad region; and
a carrier substrate coupled to the donor substrate, the carrier substrate comprising:
a first pattern for a p-type contact; and
a second pattern for an n-type contact such that the p-type contact is electrically connected to the p-type pad region and the n-type contact is electrically connected to the n-type pad region.

10. The device of claim 9 wherein the carrier substrate is selected from a sapphire substrate, a silicon substrate, a glass substrate, a silicon on insulator substrate, or a gallium and nitrogen containing substrate.

11. The device of claim 9 wherein the gallium and nitrogen containing material is unintentionally doped.

12. The device of claim 9 wherein the lower barrier material comprises GaN doped with a silicon with a concentration ranging from 6e18 atoms/cm3 to 4e19 atoms/cm3 and a thickness ranging from 5 to 12 nm.

13. The device of claim 9 wherein the blanket dielectric layer is selected from at least one of a SiO₂ (silicon dioxide), silicon nitride, silicon oxynitride, aluminum oxide (Al2O3), or ZnO (zinc oxide).

14. A method of fabricating a high-speed photodiode device, the method comprising:
providing a donor substate member comprising:
a surface region;
a nucleation material overlying the surface region of the donor substrate member;
a first gallium and nitrogen containing material overlying the nucleation material;
a sacrificial region overlying the first gallium and nitrogen containing material;
an etching stop material overlying the sacrificial region;
a second gallium and nitrogen containing material overlying the etch stop material;
a plurality of defect migration layers overlying the second gallium and nitrogen containing material, the plurality of defect migration layers comprising alternating gallium nitride and indium gallium nitride regions;
a lower barrier material overlying the plurality of defect migration layers;
a plurality of absorber layers overlying the lower barrier material, the plurality of absorber layers comprising alternating indium gallium nitride regions;
a first upper barrier material overlying the plurality of absorber layers;
a second upper barrier material overlying the first upper barrier material;
a p-type contact material overlying the second upper barrier material;
a first mesa structure configured from at least the p-type contact material, the second upper barrier material, the first upper barrier material, the plurality of absorber layers, the lower barrier material, the plurality of defect migration layers, and the second gallium and nitrogen containing material;
a blanket dielectric layer overlying the first mesa structure and configured to form a sidewall on an edge of at least the first mesa structure;
a via structure configured in the blanket dielectric layer to expose a portion of the p-type contact material;
an upper p-type contact material overlying and electrically connected to the p-type contact material through the via structure; and
an upper n-type contact material overlying the second gallium and nitrogen containing material and configured such that the upper n-type contact material and the upper p-type contact material are characterized by a planar region to align a n-type surface of the n-type contact material with a p-type surface of the upper p-type contact material;
flipping the donor substrate member;
bonding the upper n-type contact material and the upper p-type contact material to an n-type pad region and a p-type pad region, respectively, of a carrier substrate member; and
removing the donor substrate member by detaching the sacrificial region from the etch stop material.

15. The method of claim 14 wherein the donor substrate member is selected from a sapphire substrate or a gallium and nitrogen containing substrate.

16. The method of claim 14 wherein the first gallium and nitrogen containing material is unintentionally doped; and the second gallium and nitrogen containing material is unintentionally doped.

17. The method of claim 14 wherein the second gallium and nitrogen containing material comprises GaN having a thickness ranging from 5 to 45 nm.

18. The method of claim 14 wherein the first upper barrier material comprises GaN characterized by an undoped state and has thickness ranging from 6 to 12 nm.

19. The method of claim 14 wherein the etching stop material comprises AlGaN characterized by an Al composition ranging from 10 to 20%, and a thickness from 10 to 30 nm.

20. The method of claim 14 wherein the sacrificial region comprises InGaN characterized by an indium composition ranging from 12 to 18%, and a thickness from 2 to 4 nm.
